(19) United States
(12) Patent Application Publication
(10) Pub. No.: US 2024/0334733 A1
(43) Pub. Date: Oct. 3, 2024

(54) TANDEM OLED DEVICES WITH STABLE INORGANIC CHARGE GENERATION LAYERS

(71) Applicant: Adeia Semiconductor Technologies LLC, San Jose, CA (US)

(72) Inventors: Oliver Zhao, Daly City, CA (US); Cyprian Emeka Uzoh, San Jose, CA (US); Thomas Workman, San Jose, CA (US); Guilian Gao, Campbell, CA (US)

(21) Appl. No.: 18/129,653

(22) Filed: Mar. 31, 2023

(51) Int. Cl. H10K 50/19; H10K 50/13; H10K 85/30

(52) U.S. Cl. CPC H10K 50/19; H10K 50/13; H10K 85/371

(57) ABSTRACT

A tandem OLED device is formed by patterning a first side of a substrate to form a first OLED opening, forming a first material layer stack in the first OLED opening, the first material layer stack comprising a first charge generation layer (CGL) and a second CGL disposed on the first CGL. After forming the first CGL and the second CGL, a second side of the substrate, opposite the first side, is patterned to form a second OLED opening in registration with the first OLED opening. A second material layer stack is formed in the second OLED opening.

### FIELD

The present disclosure relates to organic light-emitting diodes (OLEDs) and devices including OLEDs, and in particular, devices with tandem OLEDs with stable inorganic charge generation layers (CGLs) and methods of manufacturing the same.

### BACKGROUND

Tandem OLEDs offer advantages in better power consumption and increased lifetime over standard OLEDs. However, the material used in CGLs may be a limiting factor in the stability of a tandem OLED. Accordingly, there exists a need in the art for improved tandem OLEDs with stable CGLs and methods of manufacturing the same.

### SUMMARY

Embodiments herein provide for tandem OLED device (a device including two stacked OLEDs) with stable inorganic CGLs. In some embodiments, tandem OLED devices may be applicable to two or more stacked OLEDs. Advantageously, tandem OLED devices with stable inorganic CGLs may improve stability and lifetime of an OLED display over use of organic CGLs in tandem OLED devices.

One general aspect includes a method of forming a tandem OLED device. In one embodiment, the method includes patterning a first side of a substrate to form a first OLED opening, forming a first material layer stack in the first OLED opening, the first material layer stack comprising a first CGL and a second CGL disposed on the first CGL. After forming the first CGL and the second CGL, the method further includes patterning a second side of the substrate, opposite the first side, to form a second OLED opening in registration with the first OLED opening, and forming a second material layer stack in the second OLED opening.

In some embodiments, at least one of the first CGL and the second CGL is formed of an inorganic material. In some embodiments, at least one of the first CGL and the second CGL includes an inorganic metal oxide material or a metal oxide material. In some embodiments, an inorganic metal oxide material or a metal oxide material may be a transparent conductive oxide material. When forming one or both of the first CGL and the second CGL, the substrate may be heated to a temperature that exceeds the thermal budget of one or more organic layers in the tandem OLED device. For example, one or more organic layers in a tandem OLED device may have a thermal budget where the temperature of the material may not exceed 150° C. without undesirably changing the properties thereof, such as materials having a glass transition temperature around 150° C. or below. Nonetheless, the methods provided herein enable the use of relatively high temperature processes for formation of charge generation layers that will be disposed between organic layers in the final OLED device. In some embodiments, the high temperature processes include heating the substrate to, and maintaining the substrate at, a temperature greater than (or about) 150° C. during deposition of the first and/or second CGL. Although described herein in relation to OLED displays, it is contemplated that the method may be used in any other application where it is desirable to have material layers formed using relatively high temperature processes disposed between material layers having relatively low thermal budgets.

In some embodiments, forming the first material layer stack comprises forming a first emissive/transport layer stack on the second CGL. In some embodiments, the method further includes forming a first conductive layer on the first emissive/transport layer stack. In some embodiments, the second material layer stack comprises a second emissive/transport layer stack disposed in direct contact with the first CGL and a second conductive layer disposed on the second emissive/transport layer stack. Each of the first and second OLED openings may be wider at the respective surfaces of the first and second sides of the substrate than at an interface of the first and second material layer stacks.

Another general aspect includes a tandem OLED device. Generally, the tandem OLED device includes a first material layer stack in a first OLED opening on a first side of a substrate. The first material layer stack includes a first CGL and a second CGL disposed on the first CGL. The tandem OLED device also includes a second material layer stack in a second OLED opening on a second side of the substrate, opposite the first side. The second OLED opening is in registration with the first OLED opening.

Another general aspect includes a display device. Generally, the display device includes a TFT backplane and a substrate including a plurality of tandem OLED devices. Each tandem OLED device includes a first material layer stack in a first OLED opening on a first side of the substrate. The first material layer includes a first CGL and a second CGL disposed on the first CGL. Each tandem OLED device also includes a second material layer stack in a second OLED opening on a second side of the substrate, opposite the first side. The second OLED opening is in registration with the first OLED opening.

### BRIEF DESCRIPTION OF THE DRAWINGS

The above and other objects and advantages of the disclosure will be apparent upon consideration of the following detailed description, taken in conjunction with the accompanying drawings.

FIGS. 1A-1G are illustrative schematic sectional side views of a single pixel of a tandem OLED device with stable inorganic CGL at different stages of manufacturing to illustrate aspects of the method, in accordance with embodiments of the present disclosure;

FIGS. 2A-2C are illustrative schematic sectional side views of a single pixel of a tandem OLED device with stable inorganic CGL at different stages of manufacturing corresponding to FIGS. 1A-1C to illustrate an alternative aspect of the method, in accordance with embodiments of the present disclosure;

FIGS. 3A-3B are illustrative schematic sectional side views of a single pixel of a top-emitting tandem OLED device with stable inorganic CGL with a TFT backplane, in accordance with embodiments of the present disclosure;

FIG. 4 is an illustrative schematic sectional side view of a single pixel of a bottom-emitting tandem OLED device with stable inorganic CGL with a TFT backplane, in accordance with embodiments of the present disclosure;

The figures herein depict various embodiments of the disclosure for purposes of illustration only. It will be appreciated that additional or alternative structures, assemblies, systems, and methods may be implemented within the principles set out by the present disclosure.

### DETAILED DESCRIPTION

Embodiments herein provide for tandem OLED displays and method of forming the same. In some embodiments, one or more charge generation layers of the tandem OLED devices are formed at a process temperature that exceeds the thermal budget of one or more layers of the tandem OLED stacks (referred to herein as emissive/transport layer stacks). Charge generation layers generally include an n-doped layer (e.g., n-type CGL) and a p-doped layer (e.g., p-type CGL) for injection of electrons and holes, respectively. Charge generation layers formed at relatively high temperature processes, such charge generation layers comprising inorganic materials, are generally more stable than charge generation layers formed at lower temperatures. For example, organic layer exposure to factors such as moisture, electron-induced migration, thermal diffusion of oxygen, and photochemical degradation may decrease stability and lifetime of OLEDs. Inorganic layers may be less susceptible to moisture, light and UV degradation, and oxidation in comparison to organic layers. Dense inorganic layers (e.g., high-temperature deposited inorganic layers) can prevent moisture ingress and act as barriers to atoms and molecules migrating under bias. Often, inorganic layers deposited at temperatures greater than about 150° C., such as greater than about 200° C., 400° C., or 800° C. have structural characteristics, e.g., higher crystal morphology and density, when compared to inorganic layers deposited at lower temperatures.

Thus, the use of inorganic CGLs in tandem OLED devices may provide better stability and improved device lifetime over use of organic CGLs in tandem OLED devices. However, inorganic CGLs may require higher processing temperatures than organic CGLs, which may make processing inorganic CGLs in tandem OLED devices challenging due to thermal sensitivity of the organic layers in the stack.

To help address these problems, the disclosed approach may include a method of manufacturing a tandem OLED devices with stable inorganic CGLs, where the method builds the tandem OLED from the central CGLs. The disclosed approach enables higher temperature processing of one or more CGLs of the tandem OLED device before processing layers of the tandem OLED device at lower temperatures (e.g., one or more organic layers of emissive/transport layer stacks).

Tandem OLED devices with stable inorganic CGLs may improve stability and lifetime over use of organic CGLs in tandem OLED devices.

The tandem OLED devices described herein generally include an anode, first and second emissive/transport layer stacks, a plurality of CGLs disposed between the first and second emissive/transport layer stacks, and a cathode. For example, in some embodiments, the tandem OLED device includes an anode, a hole injection layer disposed on the anode, a first emissive/transport layer stack (e.g., first hole transport layer, emissive layer, and electron transport layer), a first CGL, a second CGL, a second emissive/transport layer stack (e.g., second hole transport layer, emissive layer, and electron transport layer), an electron injection layer, and a cathode. The first CGL may be a n-type CGL (n-CGL). The second CGL may be a p-type CGL (p-CGL). The bilayer of n-CGL and p-CGL may enable charge separation to generate free charges.

As used herein, the term “substrate” means and includes any workpiece, wafer, panel, or article that provides a base material or supporting surface from which or upon which components, elements, devices, assemblies, modules, systems, or features of the tandem OLED device described herein may be formed. The term substrate also includes “OLED substrates” such as glass panels that provide a supporting material upon which elements of an OLED device are fabricated or attached, and any material layers, features, and/or electronic devices formed thereon, therein, or therethrough.

Spatially relative terms are used herein to describe the relationships between elements, such as the relationships between layers and other features described below. Unless the relationship is otherwise defined, terms such as “above,” “over,” “upper,” “upwardly,” “outwardly,” “on,” “below,” “under,” “beneath,” “lower,” and the like are generally made with reference to the drawings. Thus, it should be understood that the spatially relative terms used herein are intended to encompass different orientations of the substrate and, unless otherwise noted, are not limited by the direction of gravity. Unless the relationship is otherwise defined, terms describing the relationships between elements such as “disposed on,” “embedded in,” “coupled to,” “connected by,” “attached to,” “bonded to,” either alone or in combination with a spatially relevant term include both relationships with intervening elements and direct relationships where there are no intervening elements.

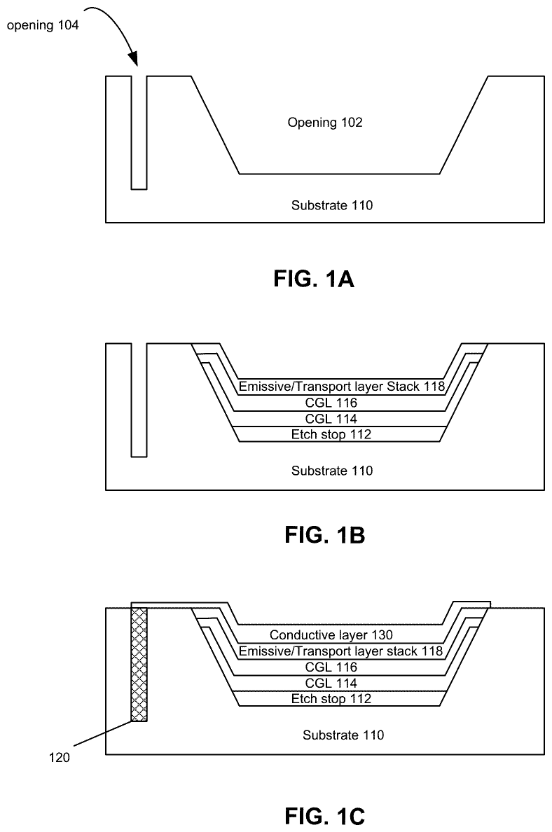

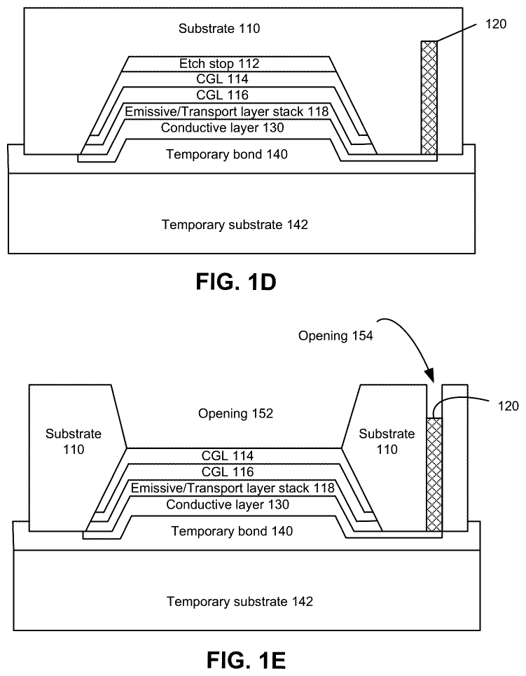

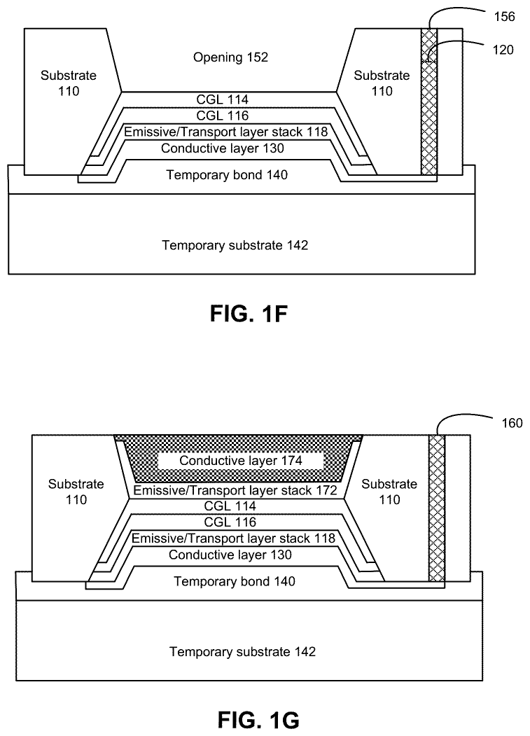

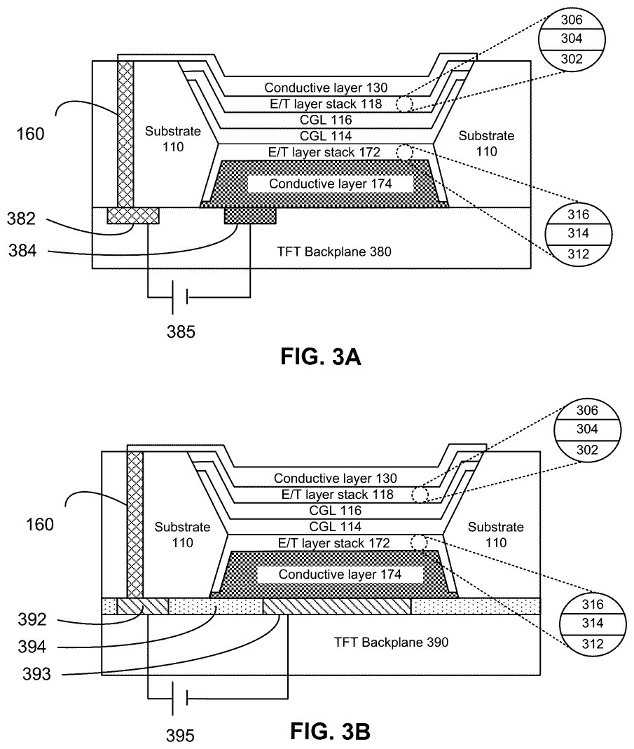

FIGS. 1A-1G illustrate aspects of a method of manufacturing a display device, such as the devices illustrated in FIGS. 3A and 3B. Generally, the method includes patterning a first side of a substrate to form a first OLED opening (FIG. 1A) and forming a first material layer stack in the first OLED opening (FIG. 1B), patterning a second side of the substrate to form a second OLED opening (FIGS. 1C-1D), and forming a second material layer stack in the second OLED opening (FIG. 1E), each of which will be discussed in turn below.

FIG. 1A shows an example of patterning a first side of a substrate 110 to form a first OLED opening 102 and a first via opening 104. In some embodiments, the substrate 110 is made of a glass material. The first OLED opening 102 and the first via opening 104 may formed using any suitable etching method for glass (e.g., wet etching, gaseous hydrogen fluoride etch, reactive ion etching, etc.).

FIG. 1B shows an example of forming a first material layer stack in the first OLED opening 102. The first material layer stack may include an etch-stop layer 112, a CGL 114, a CGL 116, and a first transport/emissive layer stack 118 formed in the OLED opening 102.

The etch-stop layer 112 may be formed in the first OLED opening 102. The etch-stop layer 112 may directly contact the substrate 110. The etch-stop layer 112 may comprise a silicon nitride material, or any suitable etch stop material.

The CGL 114 may be formed on the etch-stop layer 112 in the first OLED opening 102, and the CGL 116 may be formed on the CGL 114 in the first OLED opening 102. For example, the CGL 114 may be a p-type CGL, and the CGL 116 may be an n-type CGL. In some embodiments, the CGL 114 may be a n-type CGL, and the CGL 116 may be an p-type CGL.

A CGL may be organic or inorganic material. For example, n-type inorganic CGL materials may comprise one or more of V₂O₅, WO₃, SnO₂, and TiO₂. P-type inorganic CGL materials may comprise one or more of MoO₃, ReO₃, NiO, and CuO. N-type organic CGL materials may comprise one or more of Ag-doped Bphen, Alq₃, C60, and Rb₂CO₃ doped Bphen. P-type organic CGL materials may comprise one or more of MoO₃ doped NPB, FeCl₃ doped NPB, pentacene, and ReO₃ doped NPB. In some embodiments, the metal oxide layer may comprise Li, such as an Li doped CuO and/or NiO layer. In some embodiments, the metal oxide layer comprises cuprous oxide (Cu₂O).

Forming the CGL 114 and/or CGL 116 may cause the substrate 110 to exceed a temperature of 150° C., such as above 200° C., 400° C., 450° C., 500° C., 600° C., or 700° C., for example above about 800° C. In some embodiments, one or both of the CGL 114 and CGL 116 comprises an inorganic material formed using a process that exceeds the thermal budget of one or more materials in the first or second EM/TL stack, referred to herein as high-temperature process. High-temperature processing may refer to a deposition temperature, or a temperature of the material of layer as it is deposited. A substrate that the layer is deposited on may be at or around the deposition temperature of the material of the layer as it is deposited. High-temperature processing may refer to deposition and/or annealing of the CGL. Deposition of the CGL may be formed via a sputtering, thermal evaporation, or CVD/PECVD method. In some embodiments, an inorganic layer can be evaporated and subsequently annealed after deposition.

A high temperature processed CGL in a tandem OLED device may have certain advantages. For example, high temperature processing may increase film density of an inorganic CGL layer, and thinner CGLs may be possible with higher density films. A higher density CGL film may have improved conductivity, so that dopants may not be needed to improve conductivity of the CGL. High-temperature processed metal oxides may enable certain crystalline phases and stoichiometries and may have higher degree of crystallinity compared to low-temperature processed metal oxides which may be generally amorphous. High temperature processing may improve optoelectronic properties of the CGL such as hole injection and transport properties. In contrast, low-temperature processed metal oxides may be amorphous, and may not have improved properties as previously mentioned in regards to high-temperature processed metal oxides. A diffusion suppression layer may not be needed with a high-temperature deposited inorganic CGL which is denser and inhibit diffusion better. In tandem OLED devices, lifetimes may be limited by the stability of the CGL. Improved stability of CGL may improve the lifetimes of tandem OLED devices.

In some embodiments, at least one of the CGLs 114 and 116 is a metal material. In some embodiments, the CGL 114 or CGL 116 comprises an organic material. In some embodiments, forming the first CGL 114 and/or second CGL causes the substrate to be heated to above 150° C. For example, the substrate may be heated to any suitable temperature above 150° C. (e.g., above 200° C., 400° C., 800° C., etc.).

An emissive/transport layer stack 118 may be formed on the CGL 116 in the first OLED opening 102. The emissive/transport layer stack 118 may comprise electron transport layer, emissive layer, and hole transport layer. For example, an electron transport layer may be formed on the CGL 114 that is a p-type CGL; an emissive layer may be formed on the electron transport layer; and a hole transport layer may be formed on the emissive layer. In some embodiments, a hole transport layer may be formed on the CGL 114 that is a n-type CGL; an emissive layer may be formed on the hole transport layer; and an electron transport layer may be formed on the emissive layer. In one embodiment, forming the first material layer stack comprises forming a first emissive/transport layer stack comprising a first hole transport layer, a first emissive layer, and a first electron transport layer. In some embodiments, the hole transport layer and/or electron transport layer may be metal oxides, polymer, or small molecule material. In some embodiments, the forming of the emissive/transport layer stack 118 in the first OLED opening 102 may be performed with evaporation through fine metal masks (FMM) or any other suitable method (e.g., inkjet printing, depositing the layer and patterning with lithography process, etc.).

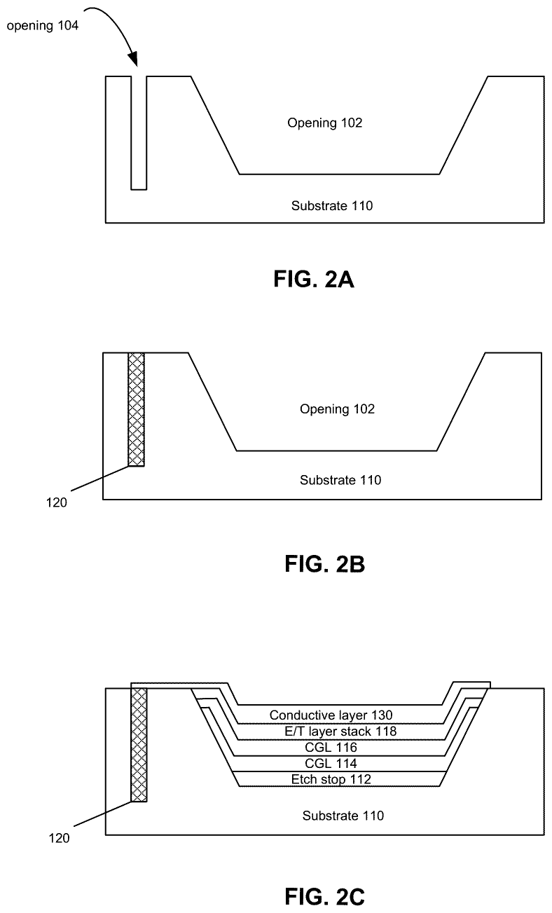

FIG. 1C shows an example of forming a conductive layer 120 in the first via opening 104. The conductive layer 120 may be copper, and the copper may be electroplated within the first via opening 104. In some embodiments, the conductive layer 120 may be printed. For example, the conductive layer 120 may be 3D printed conductive material (e.g., copper, silver, tin, indium, or their respective alloys). In some embodiments, the conductive layer 120 may be polysilicon (Poly-Si) or tungsten (W). In some embodiments, the deposition of the conductive layer 120 may be deposited before depositing the first material stack of FIG. 1B. See, for example, alternative to FIGS. 1A-1C as shown in FIGS. 2A-2C.

FIG. 1C also shows an example of forming conductive layer 130 in the first OLED opening 102. In some embodiments, the conductive layer 130 is indium tin oxide (ITO), which is formed on top of the emissive/transport layer stack 118. The conductive layer 130 may be formed in the first OLED opening 102 and in an area between the first OLED opening 102 and the first via opening 104 to electrically connect to the conductive layer 120 in the first via opening. The conductive layer 130 may be formed on the conductive layer 120 in the first via opening to electrically connect the conductive layer 130 to the conductive layer 120. In some embodiments, the conductive layer 120 or a different conductive layer/material may be formed in an area between the first OLED opening 102 and the first via opening 104 to electrically connect to the conductive layer 130 in the first OLED opening 102.

FIG. 1D shows an example of attaching a temporary substrate to the substrate to process an opposite side of substrate 110. A temporary bond 140 may be formed between a first surface of the substrate 110 (e.g., surface including the first OLED opening 102 and the first via opening 104) and a temporary substrate 142. The temporary bond 140 may be an adhesive. For example, the conductive layer 130 may be ITO that is temporary bonded to a temporary substrate. The subsequent processing steps may be processed using the temporary substrate so that a second side of substrate 110 may be processed. The temporary substrate may be made of glass.

FIG. 1E shows an example of patterning a second side of substrate 110 to form a second OLED opening 152 and a second via opening 154. In some embodiments, the substrate 110 is made of a glass material. The second OLED opening 152 and the second via opening 154 may formed using any suitable etching method for glass. The substrate 110 may be patterned until the etch-stop layer 112 is reached to form OLED opening 152. The etch-stop layer 112 may also be removed to expose a surface of the CGL 114. The etch-stop layer 112 may be removed with a dry etch with high selectivity to the etch stop. In some embodiments, the conductive layer 120 is made of copper, and copper can be used as an etch stop when forming the second via opening 154. For example, glass may be patterned by being etched with a fluoride gas, and the copper may be used as an etch stop. The substrate 110 may be patterned until conductive layer 120 is revealed in the second via opening 154.

Each of the first OLED opening 102 and the second OLED opening 152 may be wider at the respective surfaces of the first and second sides of the substrate 110 than at an interface of the first and second material layer stacks (e.g., interface of the CGL 114 and emissive/transport layer stack 172).

FIG. 1F shows an example of forming a conductive layer 156 in a second via opening 154. For example, the conductive layer 156 is formed on the conductive layer 120 in the second via opening 154. The conductive layer 156 may be formed by electroplating copper to fill the second via opening 154 with copper. The conductive layer 156 and the conductive layer 120 form via 160, as shown in FIG. 1G. In some embodiments, the via 160 is polysilicon or tungsten material.

FIG. 1G shows an example of forming a second emissive/transport layer stack 172 and a conductive layer 174 in the second OLED opening 152. The second emissive/transport layer stack 172 may include a hole transport layer, an emissive layer, and an electron transport layer. For example, the hole transport layer may be formed on the CGL 114 that is a p-type CGL; the emissive layer may be formed on the hole transport layer; and the electron transport layer may be formed on the emissive layer in the second OLED opening 152. In some embodiments, the CGL 114 is an n-type CGL, and the electron transport layer may be formed on the CGL 114; the emissive layer formed on the electron transport layer; and hole transport layer formed on the emissive layer in the second OLED opening 152. The conductive layer 174 may comprise a silver (Ag) material. The Ag material may or may not include a titanium (Ti) seed/barrier layer. The conductive layer 174 may be electroplated, evaporated, or sputtered into the second OLED opening 152.

In some embodiments, a conductive layer is deposited and the unwanted portions of the deposited conductive layer may be removed by wet etch methods or planarization methods to form the conductive layer 174 as shown in FIG. 1G. The wet etch method may comprise forming a mask layer (not shown) to protect the conductive layer 174 within the second OLED opening 152, etching off the unprotected portions of the deposited conductive layer, and stripping of the protective layer (mask layer). The formed layer (e.g., conductive layer 174) is cleaned and dried before subsequent processes. In some embodiments, an adhesion/barrier layer, for example a thin Ti layer, TiN layer, or a Ti/TiN stack may be coated over the second OLED opening 152 (e.g., formed on the emissive/transport layer stack 172 in the second OLED opening 152) before the deposition of the conductive layer 174. The thickness of the adhesion/barrier layer may be less than 100 nm, less than 50 nm, and/or less than 10 nm. The adhesion/barrier layer (e.g., Ti or TiN layer) may promote adhesion of the conductive layer 174. In some embodiments, the adhesion/barrier layer may be 1-10 nm thick. Other suitable adhesion/barrier layer materials may comprise one or more of TiW, WN, and NiV, which may be used to prevent or hinder Ag diffusion into surrounding materials. In some embodiments, the adhesion/barrier layer is less than 1 nm thick and may be deposited by physical vapor deposition.

In some embodiments, the second OLED opening 152 is patterned before the emissive/transport layer stack 118 is deposited. For example, after the CGL 116 is deposited in the first OLED opening 102 and the conductive layer 120 is deposited in the first via opening 104, a first side of the substrate 110 may be temporary bonded to a first temporary substrate. A second side of substrate 110 may be processed to etch the second OLED opening 152 and the second via opening 154. The conductive layer 156 is deposited in the second via opening 154. The conductive layers 120 and 156 form the conductive via 160 between the first and second surfaces of the substrate. After the conductive via 160 is formed, the emissive/transport layer stack 172 and the conductive layer 174 may be deposited in the second OLED opening 152, and the conductive layer 130 may be deposited on the emissive/transport layer stack 118. A second side of the substrate 110 may be bonded to a second temporary substrate, and the first temporary substrate may be released. The emissive/transport layer stack 118 and the conductive layer 130 may be formed over the CGL 116 in the first OLED opening 102. The conductive layer 130 may be formed in an area between the first OLED opening 102 and the via 160 to connect the conductive layer 130 to the via 160. A portion of the conductive layer 130 may directly contact the via 160.

In some embodiments, only one CGL comprises an inorganic material. For example, in FIG. 1B, the CGL 114 may be an inorganic layer, and the CGL 116 may be an organic layer. As an example, a process may be modified so that in FIG. 1B, the CGL 114 is deposited in the first OLED opening 102 as an inorganic layer, and the CGL 116 is deposited as an organic layer in the second OLED opening 152 during processing the second side of the substrate 110. In some embodiments, there may be a different number of CGLs. For example, there may be three CGLs, or any suitable number of layers of CGLs.

In some embodiments, the conductive layer 174 comprises a thin adhesion/barrier layer of titanium nitride (e.g., transparent and conductive, may be ALD deposited) over the organic layer, followed by a copper layer. For example, the titanium nitride may serve as an adhesion/barrier layer. Suitable examples of an adhesion/barrier layer are described above. In some embodiments, the adhesion/barrier layer may help the conductive layer 174 adhere to the organic layer. The titanium nitride may serve as a barrier layer to prevent diffusion of the conductive layer 174 to the organic layer.

FIGS. 2A-2C are illustrative schematic sectional side views of a single pixel of a tandem OLED device with stable inorganic CGL at different stages of manufacturing corresponding to FIGS. 1A-1C to illustrate an alternative aspect of the method, in accordance with embodiments of the present disclosure.

FIG. 2A is the same as FIG. 1A and is reproduced for reference for FIGS. 2B-2C, which are variations of different stages of manufacturing corresponding to FIGS. 1B-1C. FIG. 2B shows an example of forming the conductive layer 120 in the first via opening 104. The conductive layer 120 may be copper, and the copper may be electroplated within the first via opening 104. In some embodiments, the conductive layer 120 may be printed. For example, the conductive layer 120 may be 3D printed conductive material (e.g., copper, silver, tin, indium, or their respective alloys). In some embodiments, the conductive layer 120 may be polysilicon (Poly-Si) or tungsten (W).

FIG. 2C shows an example of forming the first material layer stack in the OLED opening 102, forming the conductive layer 130, and the process may continue as the same in FIGS. 1D-1G. In some embodiments, forming the first material layer stack is the same or similar as forming the first material layer stack as described in FIG. 1B. In some embodiments, forming the conductive layer 130 is the same or similar as forming the first conductive layer 130 as described in FIG. 1C.

FIGS. 3A-3B are illustrative schematic sectional side views of a single pixel of a top-emitting tandem OLED device with stable inorganic CGL with a TFT backplane (a substrate, e.g., a panel, that includes the thin film transistors (TFTs) used to control the pixels/tandem OLED devices of a display), in accordance with embodiments of the present disclosure. From FIG. 1G, the temporary bond 140 was removed from the substrate 110. In FIGS. 3A-3B, the substrate 110 may include, for example, layers with the following details. The conductive layer 130 may be an anode. The anode may be an ITO material. In some embodiments, the anode is any suitable transparent conducting oxide (e.g., IZO, FTO, etc.). The first emissive/transport layer stack 118 may comprise an electron transport layer 302, an emissive layer 304, and a hole transport layer 306. The hole transport layer 306 of first emissive/transport layer stack 118 may be in direct contact with the anode (conductive layer 130). In some embodiments, a hole injection layer may be inserted between the hole transport layer and the conductive layer 130. The CGL 116 may be an n-type CGL. The CGL 116 may be in direct contact with the electron transport layer 302 of first emissive/transport layer stack 118. The CGL 114 may be an p-type CGL. The emissive/transport layer stack 172 may include an electron transport layer 312, an emissive layer 314, and a hole transport layer 316. The hole transport layer 316 of the emissive/transport layer stack 172 may be in direct contact with the CGL 114. The electron transport layer 312 of the emissive/transport layer stack 172 may be in direct contact with the conductive layer 174. In some embodiments, although FIGS. 3A-3B show the first and second emissive/transport layer stack 118 and 172 each comprising three layers, the first and/or second emissive transport layer stack may each comprise any suitable number of layers (e.g., 1, 2, 4 or more). In some embodiments, an electron injection layer may be inserted between the electron transport layer of the emissive/transport layer stack 172 and the conductive layer 174. The conductive layer 174 may be a cathode. The cathode may be an Ag material. In some embodiments, the cathode is any suitable metal (e.g., ˜4.7 eV or lower in work function, Al, Zn, Mg, Ag, Ti, Cu, etc.). Light generated from the emissive/transport layer stack 172 and the emissive/transport layer stack 118 is emitted through the conductive layer 130 which is transparent conductive material.

In FIG. 3A, the substrate 110 is hybrid bonded to a TFT backplane 380. For example, the TFT backplane 380 may have contacts 382 and 384. The via 160 and the contact 382 may comprise a same material (e.g., copper, or any suitable conductive material). The conductive layer 174 and the contact 384 may comprise a same material (e.g., silver, or any suitable conductive material). In some embodiments the via 160 and the contact 382 may comprise different materials that may be compatible with hybrid bonding. For example, the via 160 may comprise a copper material, and the contact 384 may comprise a silver material, and the copper and silver may be hybrid bonded to form a continuous alloy. For example, the conductive layer 174 may comprise a silver material and the contact 384 may comprise a copper material, and the silver and copper may be hybrid bonded to form a continuous alloy. The substrate 110 may be hybrid bonded to the TFT backplane 380 as indicated in FIG. 3A. In some embodiments, a power source 385 may apply a voltage across the contacts 382 and 384, and light generated from the emissive/transport layer stack 172 and the emissive/transport layer stack 118 is emitted through the conductive layer 130 to exit the top-emitting tandem OLED device.

FIG. 3B shows flip chip bonding of the substrate 110 to a TFT backplane 390. For larger pitch applications (e.g., 50 microns) flip chip bonding may be used to bond the substrate 110 to the TFT backplane 390. The solder bump 392 may connect the via 160 of the substrate 110 to the TFT backplane 390. The solder bump 393 may connect the conductive layer 174 to the TFT backplane 390. The insulating adhesive 394 bonds the substrate 110 to the TFT backplane 390 while providing an insulating layer. In some embodiments, solder bump 392 and/or 393 is a conductive material printed by 3D methods. It is contemplated that printing conductive materials by 3D methods can be used to form conductive elements of any of the other embodiments described herein. In some embodiments, solder bump 392 and/or 393 is a conductive contact comprising of nanoparticles of conductive material. It is contemplated that the nanoparticles can be used to form conductive elements of any of the other embodiments described herein. In some embodiments, a power source 395 may apply a voltage across the solder bumps 392 and 393, and light generated from the emissive/transport layer stack 172 and the emissive/transport layer stack 118 is emitted through the conductive layer 130 to exit top-emitting tandem OLED device.

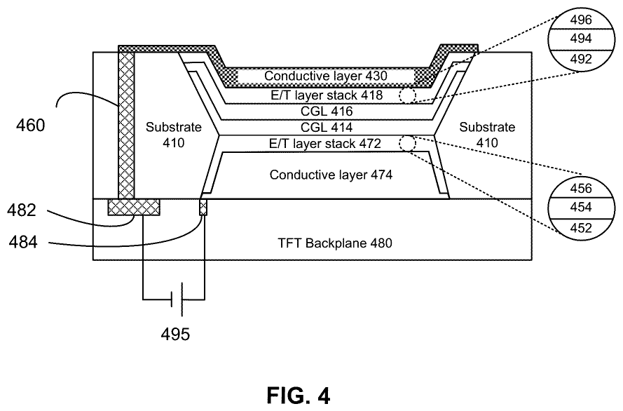

FIG. 4 is an illustrative schematic sectional side view of a single pixel of a bottom-emitting tandem OLED device with stable inorganic CGL with a TFT backplane (a substrate, e.g., a panel, that includes the thin film transistors (TFTs) used to control the pixels/tandem OLED devices of a display), in accordance with embodiments of the present disclosure. The substrate 410 may include, for example, layers with the following details. The conductive layer 474 may be an anode; a first emissive/transport layer stack 472 may comprise a hole transport layer 452, an emissive layer 454, and an electron transport layer 456; the hole transport layer 452 of the emissive/transport layer stack 472 may be in direct contact with the anode (conductive layer 474). In some embodiments, although FIG. 4 shows the first and second emissive/transport layer stack 418 and 472 each comprising three layers, the first and/or second emissive transport layer stack may each comprise any suitable number of layers (e.g., 1, 2, 4 or more). In some embodiments, a hole injection layer may be inserted between the hole transport layer of the emissive/transport layer stack 472 and the conductive layer 474. The CGL 414 may be an n-type CGL. The CGL 414 may be in direct contact with the electron transport layer 456 of the emissive/transport layer stack 472. The CGL 416 may be an p-type CGL. The emissive/transport layer stack 418 may include a hole transport layer 492, an emissive layer 494, and an electron transport layer 496. The hole transport layer 492 of the emissive/transport layer stack 472 may be in direct contact with the CGL 416, and the electron transport layer 496 of the emissive/transport layer stack 472 may be in direct contact with the conductive layer 430. In some embodiments, an electron injection layer may be inserted between the electron transport layer of the emissive/transport layer stack 418 and the conductive layer 430. The conductive layer 430 may be a cathode. Light generated from the emissive/transport layer stack 472 and the emissive/transport layer stack 418 is emitted through the conductive layer 474 which is transparent conductive material.

The substrate 410 is hybrid bonded to a TFT backplane 480. For example, the TFT backplane 480 may have contacts 482 and 484. In some embodiments, the via 460 and the contact 482 may comprise a same material (e.g., copper, or any suitable conductive material). In some embodiments, although not shown in FIG. 4, the via 460 and the contact 482 may comprise different materials. For example, the via 460 may comprise a copper material, and the contact 482 may comprise a silver material, and copper and silver may be hybrid bonded to form a continuous alloy. In some embodiments, the contact 484 of the TFT backplane 480 comprises a copper material. For example, the conductive layer 474 may be a transparent conductive oxide (e.g., ITO, IZO, FTO, etc.) and the contact 484 may comprise a copper material. The copper material may have a native oxide layer that can be hybrid bonded to the transparent conductive oxide material. In some embodiments, the contact 484 of the TFT backplane 480 comprises a silver material. For example, the conductive layer 474 may be a transparent conductive oxide (e.g., ITO, IZO, FTO, etc.) and the contact 484 may comprise a silver material. The silver material may have a native oxide layer that can be hybrid bonded to the transparent conductive oxide material. In other embodiments, the contact 484 and the conductive layer 474 comprises the same material (e.g., ITO, or any suitable transparent conductive material). In some embodiments, a power source 495 may apply a voltage across the contacts 484 and 482, and light generated from the emissive/transport layer stack 472 and the emissive/transport layer stack 418 is emitted through the conductive layer 474 and through the TFT backplane 480 to exit the bottom-emitting tandem OLED device.

In embodiments where the substrates are bonded using hybrid dielectric and metal bonds, the method may further include planarizing or recessing the metal features below the field surface before contacting and bonding the dielectric material layers. After the dielectric bonds are formed, the substrates may be heated to a temperature of 150° C. or more and maintained at the elevated temperature for a duration of about 1 hour or more, such as between 8 and 24 hours, to form direct metallurgical bonds between the metal features. Suitable direct dielectric and hybrid bonding technologies that may be used to perform aspects of the methods described herein include ZiBond® and DBI®, each of which are commercially available from Adeia, San Jose, CA, USA.

The embodiments discussed above are intended to be illustrative and not limiting. One skilled in the art would appreciate that individual aspects of the tandem OLED device, display devices, and methods discussed herein may be omitted, modified, combined, and/or rearranged without departing from the scope of the claimed subject matter. Only the claims that follow are meant to set bounds as to what the disclosed subject matter includes.

1. A method of forming a tandem OLED device, the method comprising:
patterning a first side of a substrate to form a first OLED opening;
forming a first material layer stack in the first OLED opening, the first material layer stack comprising a first charge generation layer (CGL) and a second CGL disposed on the first CGL;
after forming the first CGL and the second CGL, patterning a second side of the substrate, opposite the first side, to form a second OLED opening in registration with the first OLED opening; and
forming a second material layer stack in the second OLED opening.

2. The method of claim 1, wherein forming the first material layer stack comprises forming a first emissive/transport layer stack on the second CGL.

3. The method of claim 2, wherein the second side is patterned after forming the first emissive/transport layer stack.

4. The method of claim 2, wherein the second material layer stack comprises a second emissive/transport layer stack.

5. The method of claim 4, wherein the second emissive/transport layer stack is disposed in direct contact with the first CGL.

6. The method of claim 5, wherein each of the first and second OLED openings are wider at the respective surfaces of the first and second sides of the substrate than at the interface of the first and second material layer stacks.

7. The method of claim 5, wherein the first material layer stack further comprises a first conductive layer disposed on the first emissive/transport layer stack, and the second material layer stack comprises a second conductive layer disposed on the second emissive/transport layer stack.

8. The method of claim 7, wherein the first conductive layer is an anode, the second conductive layer is a cathode, and the method further comprises:
bonding the second conductive layer to a TFT-backplane to form a top-emitting display device.

9. The method of claim 7, wherein the first conductive layer is a cathode, the second conductive layer is an anode, and the method further comprises:
bonding the second conductive layer to a TFT-backplane to form a bottom-emitting display device.

10. The method of claim 1, further comprising attaching the substrate to a TFT-backplane using hybrid bonds.

11. The method of claim 1, further comprising attaching the substrate to a TFT-backplane using solder bumps.

12. The method of claim 1, wherein at least one of the first CGL and the second CGL comprise an inorganic material.

13. The method of claim 1, wherein at least one of the first CGL and the second CGL comprise an inorganic metal or inorganic metal oxide material.

14. The method of claim 1, wherein forming one or both of the first CGL and the second CGL comprises heating the substrate to a temperature greater than about 200° C.

15. The method of claim 1, wherein forming one or both of the first CGL and the second CGL comprises heating the substrate to a temperature greater than about 400° C.

16. The method of claim 1, wherein forming one or both of the first CGL and the second CGL comprises heating the substrate to a temperature greater than about 800° C.

17. The method of claim 1, further comprising:
before forming the second OLED opening, forming an etch-stop layer in the first OLED opening; and
removing the etch-stop layer when forming the second OLED opening.

18. The method of claim 1, further comprising forming a conductive via between the first side and the second side of the substrate.

19. The method of claim 18, wherein forming the conductive via comprises patterning the first side of the substrate to form a first via opening and patterning the second side of the substrate to form a second via opening in registration with the first via opening.

20. The method of claim 18, wherein the conductive via comprises a copper material.

21-48. (canceled)
